(19) United States
(12) Patent Application Publication
(10) Pub. No.: US 2025/0364470 A1
(43) Pub. Date: Nov. 27, 2025

(54) SEMICONDUCTOR PACKAGE STRUCTURE AND METHOD FOR MANUFACTURING THE SAME

(71) Applicant: Taiwan Semiconductor Manufacturing Company, Ltd., Hsinchu (TW)

(72) Inventor: Tzuan-Horng Liu, Taoyuan City (TW)

(73) Assignee: Taiwan Semiconductor Manufacturing Company, Ltd., Hsinchu (TW)

(21) Appl. No.: 18/675,090

(22) Filed: May 27, 2024

(51) Int. Cl. H01L 23/00; H01L 25/10

(52) U.S. Cl. CPC H01L 24/16; H01L 24/04; H01L 24/32; H01L 24/73; H01L 24/81; H01L 24/20; H01L 25/105; H01L 2224/0401; H01L 2224/16145; H01L 2224/211; H01L 2224/32145; H01L 2224/73204; H01L 2224/81948; H01L 2225/1023; H01L 2924/1815

(57) ABSTRACT

A semiconductor package structure includes a first die having a first bonding surface, a second die having a second bonding surface in which the second bonding surface faces the first bonding surface, and an intermediate structure between the first bonding surface and the second bonding surface. The intermediate structure includes a plurality of traces over the first bonding surface, a plurality of microbumps over the second bonding surface, and a plurality of joint parts between the traces and the microbumps, wherein the joint parts include an intermetallic compound.

### BACKGROUND

The semiconductor integrated circuit (IC) industry has experienced exponential growth. Technological advances in IC materials and design have produced generations of ICs where each generation has smaller and more complex circuits than the previous generation. Each integrated circuit die may include many input/output pads to communicate with other components to be packaged with the integrated circuit die. Accordingly, a three-dimensional (3D) die stacking has been developed got packaging integrated circuit dies. However, there are quite a few challenges to be handled for the technologies of advanced packaging.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 illustrates a cross-sectional view of a semiconductor package structure in accordance with some embodiments of the present disclosure.

FIG. 2 illustrates a cross-sectional view of an intermediate step for manufacturing a semiconductor package structure in accordance with some embodiments of the present disclosure.

FIG. 3 illustrates an enlarged view of an exemplary portion in the region III of the package structure of FIG. 2.

FIG. 4A illustrates a layout diagram in a plan view of an exemplary portion of a semiconductor package structure in accordance with some embodiments of the present disclosure.

FIG. 4B illustrates a layout diagram in a plan view of an exemplary portion of a semiconductor package structure in accordance with some embodiments of the present disclosure.

FIG. 5 illustrates a plan view of one microbump in accordance with some embodiments of the present disclosure.

FIG. 6 illustrates a cross-sectional view of a semiconductor package structure in accordance with some embodiments of the present disclosure.

FIG. 7 illustrates a cross-sectional view of a semiconductor package structure in accordance with some embodiments of the present disclosure.

FIG. 8 illustrates a layout diagram in a plan view of a semiconductor device in correspondence with the semiconductor package structure of FIG. 7.

FIG. 9A shows a layout diagram in a plan view of the intermediate structure in correspondence with the semiconductor device of FIG. 8.

FIG. 9B shows a layout diagram in a plan view of the intermediate structure in correspondence with the semiconductor device of FIG. 8.

FIG. 10 illustrates a cross-sectional view of a semiconductor package structure in accordance with some embodiments of the present disclosure.

FIG. 11 illustrates a layout diagram in a plan view of a semiconductor device in correspondence with the semiconductor package structure of FIG. 10.

FIGS. 12 through 19 are cross-sectional views of a process for the formation of a semiconductor package structure in accordance with some embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, it will be understood that when an element is referred to as being “connected to” or “coupled to” another element, it may be directly connected to or coupled to the other element, or one or more intervening elements may be present. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “on,” “over,” “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

The present disclosure relates to a package for Die-to-Die (D2D) interconnection structure. Particularly, the present disclosure is directed to an integrated package including a System on Chip (SoC) package bonded to an Integrated Fan-Out (InFO) package in accordance with various embodiments. The present disclosure presents a 3D stacking structure with variety types including (1) Package structure in the absence of under-ball metallurgy (UBM) pads and protective layer thereon in whole chip; (2) Package structure in which some regions (such as Core D2D talk fine pitch area and peripheral IO area) have no UBM, while other regions keep UBM. In this way, a cost-effectiveness, fine-pitch (8-25 μm) microbump structure with high strength and rigidity can be provided for high performance mobile application (e.g. accelerated processing unit (APU), central processing unit (CPU), graphics processing unit (GPU), field-programmable gate array (FPGA), Memory, etc.). However, the present disclosure is not limited thereto.

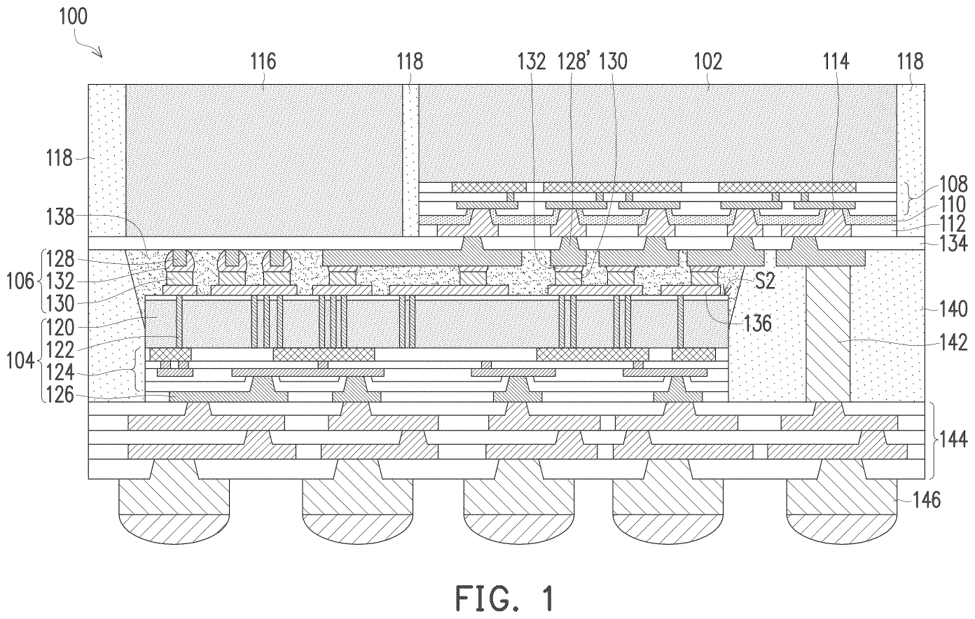

FIG. 1 illustrates a cross-sectional view of a semiconductor package structure 100 in accordance with some embodiments of the present disclosure.

Referring to FIG. 1, the semiconductor package structure 100 includes at least three parts. One part contains a first die 102, another one contains a second die 104, and yet another part is an intermediate structure 106. In some embodiments, the first die 102 may include one or more logic dies (e.g., CPU die, GPU die, FPGA die, application specific integrated circuit (ASIC) die, system-on-chip (SoC) die, system-on-integrated-chip (SoIC) die, microcontroller die, or the like), memory dies (e.g., dynamic random access memory (DRAM) die, static random access memory (SRAM) die, high bandwidth memory (HBM) die, or the like), power management dies (e.g., power management integrated circuit (PMIC) die), radio frequency (RF) dies, sensor dies, micro-electro-mechanical-system (MEMS) dies, signal processing dies (e.g., digital signal processing (DSP) die), front-end dies (e.g., analog front-end (AFE) die), the like, or a combination thereof. The first die 102 has a first bonding surface S1 for bonding to another die or substrate. In some embodiments, there are variety connection structures and lines at the first bonding surface S1; for instance, an interconnect structure 108 such as BEOL (back end of line) portion, a plurality of dielectric layers 110-112, and a plurality of connectors 114, and so on. In some embodiments, the interconnect structure 108 includes an insulative layer (represented by white areas) and a plurality of conducive patterns (represented by patterns areas) embedded in the insulative layer. The number of the insulative layers or the conducive patterns is not limited by the disclosure. In some embodiments, the conductive patterns of the interconnect structure 108 are electrically connected to the first die 102. In some embodiments, the connectors 114 are disposed on the interconnect structure 108 to electrically connect the first die 102 with the intermediate structure 106. In some embodiments, the connectors 114 may include conductive lines and conductive vias connecting levels of conductive lines to one another. The connectors 114 may be formed of a conductive material, such as a metal (e.g. copper, cobalt, aluminum, gold, combinations thereof, or the like). The dielectric layer 110 and the dielectric layer 112 may be different materials, but it is not limited thereto. In some embodiments, dielectric materials for the dielectric layers 110-112 include a polymer such as polybenzoxazole (PBO), polyimide (PI), a benzocyclobuten (BCB) based polymer, or the like. Other dielectric materials may also be used, including oxides such as silicon oxide or aluminum oxide; nitrides such as silicon nitride; carbides such as silicon carbide; the like; or combinations thereof such as silicon oxynitride, silicon oxycarbide, silicon carbonitride, silicon oxycarbonitride or the like.

In addition, a dummy die 116 may be disposed at one side of the first die 102. In some embodiments, the dummy die 116 may comprise a same material as the substrate of the first die 102. In such embodiments, the dummy die 116 and the first die 102 may have substantially similar coefficients of thermal expansion (CTEs), which may prevent the damage of the semiconductor package structure 100 due to the CTE mismatch. In some embodiments, the dummy die 116 may not comprise active and/or passive devices and may not provide addition electrical functionality to the semiconductor package structure 100. In some embodiments, the dummy die 116 may be configured as heat dissipation structure that transfer heat away from the first die 102. Accordingly, the dummy die 116 may also be referred to as heat dissipation structure.

The first die 102 and the dummy die 116 may be encapsulated in an encapsulant 118. In some embodiments, the encapsulant 118 may comprise a molding compound, such as an epoxy, a resin, a moldable polymer, a combination thereof, or the like. The molding compound may be applied while substantially liquid, and then may be cured through a chemical reaction, such as in an epoxy or resin. In other embodiments, the molding compound may be an ultraviolet (UV) or thermally cured polymer applied as a gel or malleable solid capable of being disposed around and between the first die 102 and the dummy die 116.

The second die 104 has a second bonding surface S2, and the second bonding surface S2 faces the first bonding surface S1. In some embodiments, the second die 104 may be a through semiconductor vias (TSV) die. In some embodiments, the second die 104 includes a semiconductor substrate 120, a plurality of TSVs 122, an interconnect structure 124, and a plurality of connectors 126. In some embodiments, the semiconductor substrate 120 is made of a suitable elemental semiconductor, such as crystalline silicon, diamond, or germanium; a suitable compound semiconductor, such as gallium arsenide, silicon carbide, indium arsenide, or indium phosphide; or a suitable alloy semiconductor, such as silicon germanium carbide, gallium arsenic phosphide, or gallium indium phosphide. In some embodiments, the semiconductor substrate 120 may include active components (e.g., transistors or the like) and/or passive components (e.g., resistors, capacitors, inductors, or the like) formed therein. In some embodiments, the TSVs 122 are embedded in the semiconductor substrate 120. In some embodiments, a material of the TSVs 122 includes aluminum, titanium, copper, nickel, tungsten, or alloys thereof. In some embodiments, the interconnect structure 124 may be BEOL and include a plurality of dielectric layers (represented by white areas) and a plurality of conducive patterns (represented by patterns areas) embedded in the dielectric layers. The number of the dielectric layers or the conducive patterns is not limited by the disclosure. In some embodiments, dielectric materials for the dielectric layers of the interconnect structure 124 include a polymer such as PBO, PI, a BCB based polymer; alternatively, oxides such as silicon oxide or aluminum oxide; nitrides such as silicon nitride; carbides such as silicon carbide; the like; or combinations thereof such as silicon oxynitride, silicon oxycarbide, silicon carbonitride, silicon oxycarbonitride or the like. In some embodiments, the conductive patterns of the interconnect structure 124 are electrically connected to the active components and/or the passive components embedded in the semiconductor substrate 120. The connectors 126 may include conductive lines and conductive vias connecting levels of conductive lines to one another. In some embodiments, the connectors 126 are disposed on the interconnect structure 124 to electrically/physically connect the second die 104 with other components. In some embodiments, the connectors 126 may be formed of a conductive material, such as a metal (e.g. copper, cobalt, aluminum, gold, combinations thereof, or the like).

Referring to FIG. 1 again, the intermediate structure 106 is between the first bonding surface S1 and the second bonding surface S2. The intermediate structure 106 at least includes a plurality of traces 128 over the first bonding surface S1, a plurality of microbumps 130 over the second bonding surface S2, and a plurality of joint parts 132 between the traces 128 and the microbumps 130. The sidewalls and top surface of the trace 128 are in direct contact with the joint part 132 in FIG. 1. In some embodiments, the joint parts 132 are formed on the microbumps 130 with a solder material, and then the traces 128 are bonded to the microbumps 130 via the joint parts 132. Once in place, a reflow process may be performed in order to shape the solder material into the desired bump shape and form the joint parts 132. Since the solder material contains tin and the traces 128 may be formed of copper, the joint parts 132 can comprise an intermetallic compound (IMC). In some embodiment, the intermetallic compound is a copper-rich compound such as Cu₆Sn₅ or Cu₃Sn for better electromigration resistance and reliability performance. In some embodiments, each of the joint parts 132 contains 50 vol. % or more of the intermetallic compound based on a total volume of each of the joint parts 132. In some embodiments, each of the joint parts 132 contains substantially 100 vol. % of the intermetallic compound based on a total volume of each of the joint parts 132. In some embodiments, the traces 128 are formed over the first bonding surface S1, and a dielectric cap layer 134 may be disposed between the traces 128 and the first bonding surface S1 of the first die 102. In some embodiments, traces 128′ as a redistribution layer penetrate through the dielectric cap layer 134 to electrically connect with the connectors 114. The traces 128′ of the intermediate structure 106 are in direct contact with the connectors 114 of the first die 102 at the first bonding surface S1, and thus other connection structures cab be omitted to save manufacture cost. In some embodiments, the traces 128 of the intermediate structure 106 are in direct contact with the dielectric cap layer 134, and the dielectric cap layer 134 is in direct contact with the dummy die 116. In one embodiment, the traces 128 and the traces 128′ are formed of the same material and made by the same process, but it is not limited thereto. In some embodiments, the traces 128 and the traces 128′ may be formed of a conductive material, such as a metal (e.g. copper, or the like). In some embodiments, a dielectric material of the dielectric cap layer 134 include a polymer such as PBO, PI, a BCB based polymer, or the like. Other dielectric materials may also be used, including oxides such as silicon oxide or aluminum oxide; nitrides such as silicon nitride; carbides such as silicon carbide; the like; or combinations thereof such as silicon oxynitride, silicon oxycarbide, silicon carbonitride, silicon oxycarbonitride or the like.

In some embodiments, the microbumps 130 are formed over the second bonding surface S2, and a plurality of traces 136 may be disposed between the microbumps 130 and the surface bonding surface S2 of the second die 104. In some embodiments, the microbumps 130 are electrically connected with the TSVs 122 of the second die 104 through the plurality of traces 136. In some embodiments, the traces 136 of the intermediate structure 106 are in direct contact with the TSVs 122 of the second die 104 at the second bonding surface S2. In some embodiments, the traces 136 may be formed of a conductive material, such as a metal (e.g. copper, cobalt, aluminum, gold, combinations thereof, or the like). In some embodiments, the microbumps 130 are in direct contact with the traces 136. In some embodiments, each of the microbumps 130 has a larger line width than that of at lest one of the traces 128. In some embodiments, the microbumps 130 may be formed of a conductive material, such as a metal (e.g. copper, cobalt, aluminum, gold, combinations thereof, or the like).

In some embodiments, an underfill layer 138 may be formed around the intermediate structure 106 and between the first die 102 and the second die 104, and between the dummy die 116 and the second die 104. The underfill layer 138 may be formed continuously as one layer under the first die 102 and the dummy die 116. In some embodiments, the underfill layer 138 may be in direct contact with sidewalls of the semiconductor substrate 120 of the second die 104. The underfill layer 138 may comprise a molding compound, such as an epoxy, a resin, a moldable polymer, a combination thereof, or the like. The molding compound may be applied while substantially liquid, and then may be cured through a chemical reaction, such as in an epoxy or resin. In other embodiments, the molding compound may be an UV or thermally cured polymer applied as a gel or malleable solid capable of being disposed around and between the first die 102 and the second die 104.

In some embodiments, the second die 104 and the intermediate structure 106 may be encapsulated in an encapsulant 140. In some embodiments, the encapsulant 140 may comprise a molding compound, such as an epoxy, a resin, a moldable polymer, a combination thereof, or the like. For example, the molding compound is polyimide, polyphenylene sulfide (PPS), polyether ether ketone (PEEK), polyethersulfone (PES), or the like. The molding compound may be applied while substantially liquid, and then may be cured through a chemical reaction, such as in an epoxy or resin. In other embodiments, the molding compound may be an UV or thermally cured polymer applied as a gel or malleable solid capable of being disposed around and between the second die 104 and the intermediate structure 106.

In some embodiments, a through integrated fan-out via (TIV) 142 is formed aside the second die 104 and the intermediate structure 106, and the top surface of the TIV 142 is in direct contact with at least one of the traces 128′ of the intermediate structure 106. However, the present disclosure is not limited thereto. In some embodiments, the TIV 142 includes copper, nickel, solder, alloys thereof, or the like. In some embodiments, the TIV 142 includes a seed layer and a conductive layer formed thereon (not shown). The seed layer is, for example, a titanium or/and copper composited layer. The conductive layer is, for example, a copper layer. In some embodiments, the TIV 142 further include a barrier layer (not shown) under the seed layer to prevent metal diffusion. The material of the barrier layer includes, for instance, metal nitride such as titanium nitride, tantalum nitride, or a combination thereof. In some embodiments, the TIV 142 is also encapsulated in the encapsulant 140.

In some embodiments, a redistribution layer (RDL) structure 144 is disposed below the second die 104. In some embodiments, the RDL structure 144 includes a plurality of polymer layers (represented by white areas) and a plurality of redistribution layers (represented by patterns areas) stacked alternately. The number of the polymer layers or the redistribution layers is not limited by the disclosure. In some embodiments, the polymer layers respectively include a photo-sensitive material such as PBO, PI, a BCB based polymer, or the like. In some embodiments, the redistribution layers respectively include conductive materials. The conductive material includes metal such as copper, nickel, titanium, a combination thereof or the like. In some embodiments, the redistribution layers of the RDL structure 144 are electrically connected to the connectors 126 of the second die 104. In addition, at least one of the redistribution layers may be electrically connected to the TIV 142. In some embodiments, a plurality of conductive connectors 146 are formed on and electrically connected to the redistribution layers of the RDL structure 144 to allow for the electrical coupling of the semiconductor package structure 100 to external circuits or devices. In some embodiments, the conductive connectors 146 are made of a conductive material with low resistivity, such as Sn, Pb, Ag, Cu, Ni, Bi or an alloy thereof, and are formed by a suitable process such as evaporation, plating, ball drop, or screen printing. In alternative embodiments, the conductive connectors 146 may be ball grid array (BGA) connectors, controlled collapse chip connection (C4) bumps, electroless nickel-electroless palladium-immersion gold technique (ENEPIG) formed bumps, or the like.

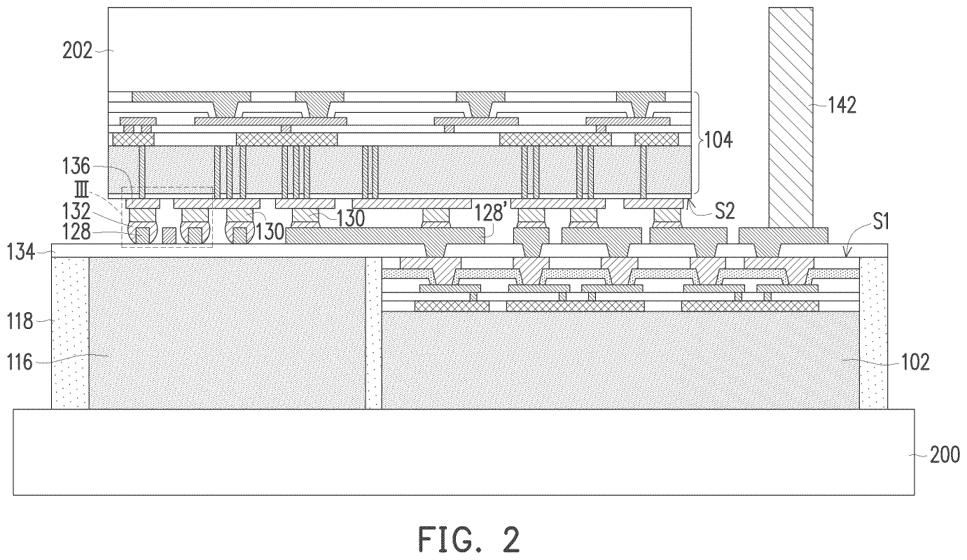

FIG. 2 illustrates a cross-sectional view of an intermediate step for manufacturing a semiconductor package structure in accordance with some embodiments of the present disclosure. In FIG. 2, a similar structure as that described above with respect to FIG. 1 is illustrated where like reference numerals indicate like elements.

Since FIG. 2 is similar to a flipped structure of FIG. 1, the first die 102 is located below the second die 104. In some embodiments, a carrier 200 is provided to carry the first die 102 and the dummy die 116 for packaging processes such as die reconstitution process, RDL formation, and/or TIV formation. In some embodiments, the carrier 200 is a glass substrate, but it is not limited thereto. In some embodiments, another carrier 202 is provided to support the second die 104 for the formation of the traces 136, the microbumps 130 and the joint parts 132. The intermediate step in FIG. 2 is to joint the second die 104 and the first die 102 via the joint parts 132, and the difference in FIG. 2 is the traces 128 having a dense layout in the region III.

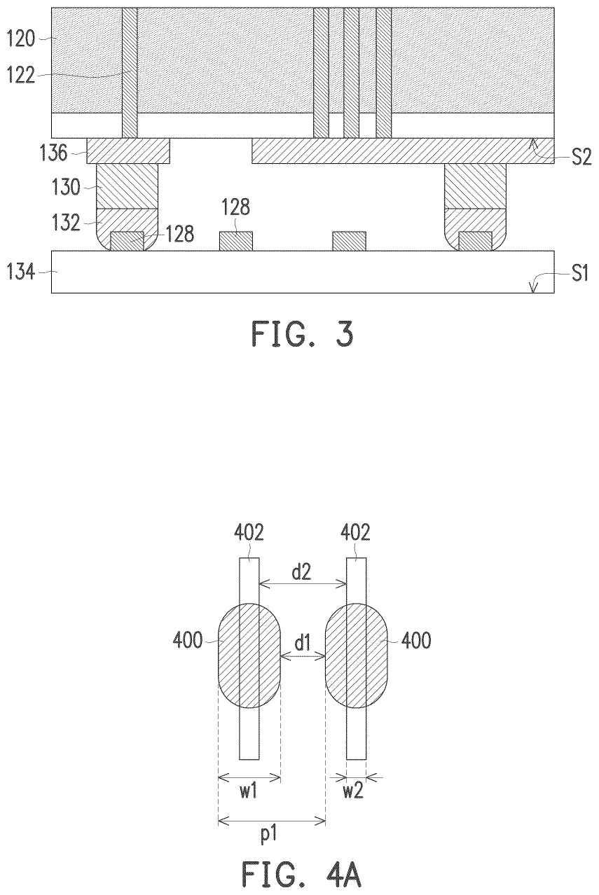

FIG. 3 illustrates an enlarged view of an exemplary portion in the region III of the package structure of FIG. 2. In FIG. 3, a similar structure as that described above with respect to FIG. 2 is illustrated where like reference numerals indicate like elements. The number of the microbumps 130 are not the same as that of the traces 128, and some of the traces 128 may be disposed between two of the microbumps 130. Therefore, the layout design of the redistribution layer may be adjusted based on the electrical requirements of the products.

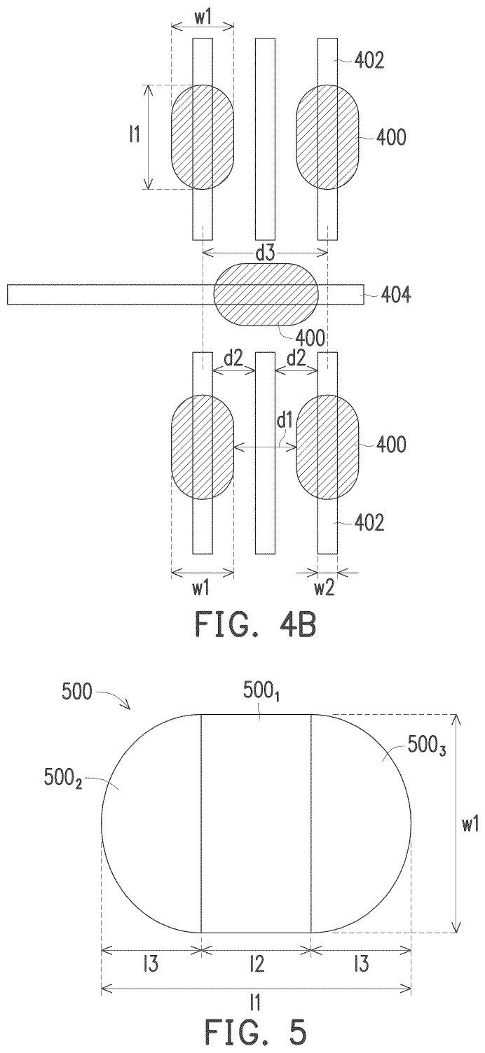

FIG. 4A illustrates a layout diagram in a plan view of an exemplary portion of a semiconductor package structure in accordance with some embodiments of the present disclosure. In FIG. 4A, two microbumps 400 and two traces 402 are shown to clarify the relative location relationship, wherein no trace is between the two microbumps 400. However, the number of traces and microbumps is not limited to two. The microbump 400 has an oblong shape in FIG. 4A, but it is not limited thereto. In another embodiment, the microbump 400 has a rectangle shape or a round shape. In terms of locations and material types, the microbumps 400 are identical or similar to the microbumps 130 in FIG. 1, and the traces 402 are identical or similar to the traces 128 in FIG. 1. In some embodiments, a width w1 of the microbump 400 is larger than a width w2 of the trace 402, and the width w1 may be, for example, a dimension of the short axis of the oblong shape. 7101 In one embodiment, if the width w2 of the trace 402 is 5 μm, a distance d2 between the two traces 402 is 20 μm and the width w1 of the microbump 400 is 15 μm, a distance d1 between the two microbumps 400 may be 10 μm, and a pitch p1 of the microbumps 400 is 25 μm. In other embodiment, if the width w2 of the trace 402 is 2 μm, a distance d2 between the two traces 402 is 6 μm and the width w1 of the microbump 400 is 4 μm, a distance d1 between the two microbumps 400 may be 4 μm, and a pitch p1 of the microbumps 400 is 8 μm. However, the present disclosure is not limited thereto. The width, the distance and the pitch can be adjusted based on the design of the products.

FIG. 4B illustrates a layout diagram in a plan view of an exemplary portion of a semiconductor package structure in accordance with some embodiments of the present disclosure. In FIG. 4B, two sets of traces 402, one lateral trace 404 extending between the two sets of traces 402, and five microbumps 400 are shown to clarify the relative location relationship. In one set of traces 402, a trace 400 without corresponding microbump is disposed between two traces. The microbump 400 has an oblong shape in FIG. 4B, but it is not limited thereto. In another embodiment, the microbump 400 has a rectangle shape or a round shape. In some embodiments, the width w1 of the microbump 400 is larger than the width w2 of the trace 402 (or the trace 404), and the ratio in width may refer to the range as described above with respect to FIG. 4A. In one embodiment, if the width w2 of the trace 402 (and the trace 404) is 5 μm, the distance d2 between the two traces 402 is 10 μm, a length 11 of the microbump 400 is 20 μm, and the width w1 of the microbump 400 is 15 μm, the distance d1 between the two microbumps 400 may be 15 μm, and the pitch (or a distance) d3 between two microbumps 400 may be 30 μm. In other embodiment, if the width w2 of the trace 402 is 2 μm, the distance d2 between the two traces 402 is 2 μm, the length 11 of the microbump 400 is 6 μm, and the width w1 of the microbump 400 is 4 μm, the distance d1 between the two microbumps 400 may be 4 μm, and the pitch d3 between two microbumps 400 may be 8 μm. However, the present disclosure is not limited thereto. The width, the distance and the length can be adjusted based on the design of the products.

FIG. 5 illustrates a plan view of one microbump in accordance with some embodiments of the present disclosure. In FIG. 5, the microbump 500 has an oblong shape and consists of a rectangle portion 500₁ and two semicircle portions 500₂-500₃. The rectangle portion 500₁ is between the two semicircle portions 500₂-500₃. The width w1 of the microbump 500 is equal to the diameter of each of the two semicircle portions 500₂-500₃, and the width w1 of the microbump 500 is also equal to the width of the rectangle portion 500₁. The length 11 of the microbump 500 is a total of the length 12 of the rectangle portion 500₁, the radius 13 of the semicircle portion 500₂ and the radius 13 of the semicircle portion 500₃. In some embodiments, the width w1, the length 11 and corresponding area of the microbump 500 may be selected from Table 1 below. However, the present disclosure is not limited thereto.

TABLE 1

| Width (μm) | Length (μm) | Area (μm²) |
|---|---|---|
| 15 | 20 | 252 |
| 12 | 16 | 161 |
| 10 | 13 | 109 |
| 8 | 11 | 74 |
| 4 | 6 | 21 |

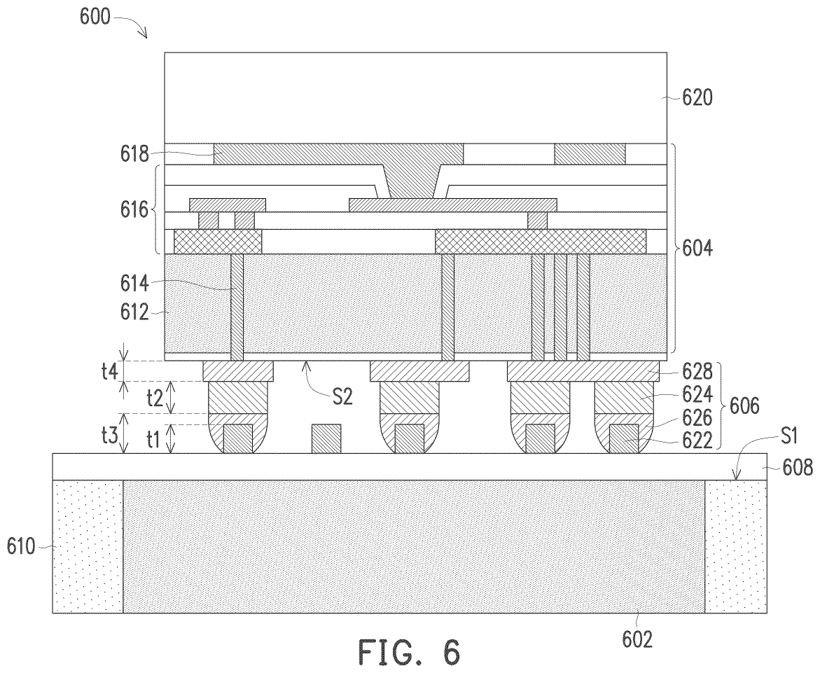

FIG. 6 illustrates a cross-sectional view of a semiconductor package structure 600 in accordance with some embodiments of the present disclosure.

Referring to FIG. 6, the semiconductor package structure 600 includes at least three parts. One part contains a first die 602, another one contains a second die 604, and yet another part is an intermediate structure 606. The first die 602 is identical or similar to the first die 102 in FIG. 1, and thus the detail is not repeated herein. The first die 602 may be encapsulated in an encapsulant 610. In some embodiments, the encapsulant 610 may comprise a molding compound as described above with respect to FIG. 1. A dielectric cap layer 608 may be disposed on the first die 602 and a top of the encapsulant 610. In some embodiments, a dielectric material of the dielectric cap layer 610 include a polymer such as PBO, PI, a BCB based polymer, or the like. Other dielectric materials may also be used, including oxides such as silicon oxide or aluminum oxide; nitrides such as silicon nitride; carbides such as silicon carbide; the like; or combinations thereof such as silicon oxynitride, silicon oxycarbide, silicon carbonitride, silicon oxycarbonitride or the like. The second die 604 may be a TSV die containing a semiconductor substrate 612, a plurality of TSVs 614, an interconnect structure 616, and a plurality of connectors 618. The second die 604 is identical or similar to the second die 104 in FIG. 1, and thus the detail of the semiconductor substrate 612, the TSVs 614, the interconnect structure 616, and the connectors 618 is also identical or similar to the semiconductor substrate 120, the TSVs 122, the interconnect structure 124 and the connectors 126, and are not repeated herein. In addition, a carrier 620 is provided to support the second die 604, and a RDL structure (not shown) may be formed over the surface covered by the carrier 620 in subsequent processes after the carrier 620 is removed.

Referring to FIG. 6 again, the intermediate structure 606 is between the first bonding surface S1 and the second bonding surface S2. The intermediate structure 606 includes a plurality of first traces 622 over the first bonding surface S1, a plurality of second traces 628 under the second bonding surface S2, a plurality of microbumps 624 under the second traces 628, and a plurality of joint parts 626 between the first traces 622 and the microbumps 624. In some embodiments, a thickness t3 of the joint parts 626 is thicker than a thickness t1 of the first traces 622. In some embodiments, a thickness t2 of the microbumps 624 is thicker than a thickness t4 of the second traces 628. In some embodiments, the microbumps 624 may be formed of a conductive material, such as a metal (e.g. copper, cobalt, aluminum, gold, combinations thereof, or the like). In some embodiments, each of the joint parts 626 is in direct contact with sidewalls and top surface of one of the first traces 622. In some embodiments, the joint parts 626 are formed on the microbumps 624 with a solder material, and then the first traces 622 are bonded to the microbumps 624 via the joint parts 626. Once in place, a reflow process may be performed in order to shape the solder material into the desired bump shape and form the joint parts 626. Since the solder material contains tin and the first traces 622 may be formed of copper, the joint parts 626 can comprise an intermetallic compound (IMC). In some embodiment, the intermetallic compound is a copper-rich compound such as Cu₆Sn₅ or Cu₃Sn for better electromigration resistance and reliability performance. In some embodiments, each of the joint parts 626 contains 50 vol. % or more of the intermetallic compound based on a total volume of each of the joint parts 626. In some embodiments, each of the joint parts 626 contains substantially 100 vol. % of the intermetallic compound based on a total volume of each of the joint parts 626. In some embodiments, the second traces 628 may be formed of a conductive material, such as a metal (e.g. copper, cobalt, aluminum, gold, combinations thereof, or the like).

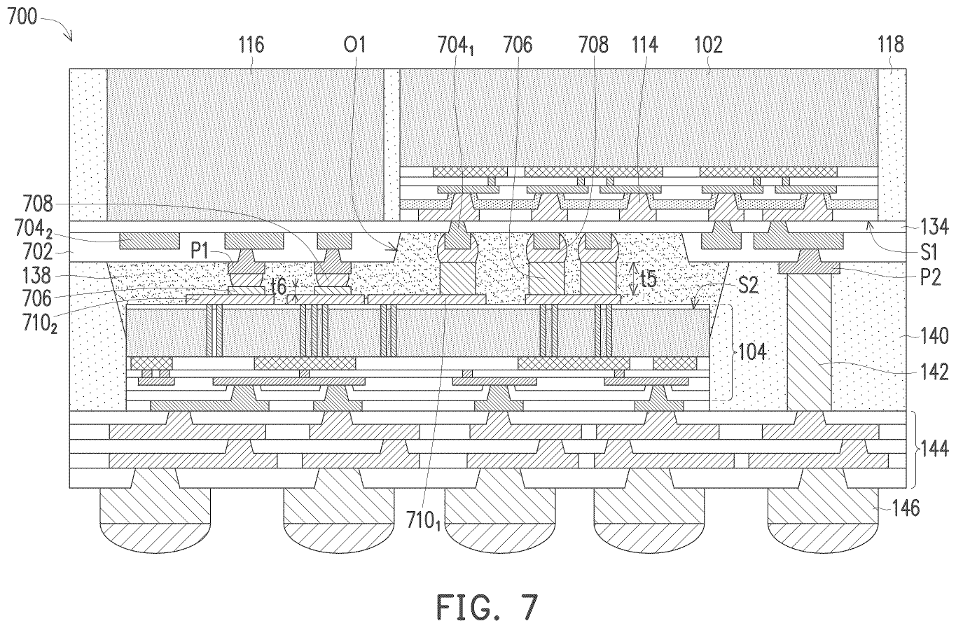

FIG. 7 illustrates a cross-sectional view of a semiconductor package structure 700 in accordance with some embodiments of the present disclosure. In FIG. 7, a similar structure as that described above with respect to FIG. 1 is illustrated where like reference numerals indicate like elements.

Referring to FIG. 7, the semiconductor package structure 700 includes a first die 102, a protective layer 702, a plurality of under-ball metallurgy (UBM) pads P1 and P2, a second die 104, a plurality of microbumps 706, and a plurality of joint parts 708. The difference between the semiconductor package structure 700 and the semiconductor package structure 100 of FIG. 1 is the structure between the first bonding surface S1 of the first die 104 and the second bonding surface S2 of the second die 104.

In. FIG. 7, a plurality of first traces 704₁-704₂ is disposed over the first bonding surface S1, and a plurality of second traces 710₁-710₂ is disposed over the second bonding surface S2, wherein the first traces 704₁-704₂ divide into a first portion 704₁ and a second portion 704₂. A protective layer 702 is formed over the first traces 704₁-704₂, wherein the protective layer 702 has at least one opening O1 exposing a first portion 704₁. The second portion 704₂ is covered by the of the protective layer 702. In some embodiments, a material of the protective layer 702 include a polymer such as PBO, PI, a BCB based polymer, or the like. The first traces 704₁-704₂ are identical or similar to the first traces 622 in FIG. 6, and thus the detail is not repeated herein. The UBM pads P1 and P2 are formed on the protective layer 702 and penetrates through the protective layer 702 to electrically connect with a second portion 704₂. The second traces 710₁-710₂ also divide into a first portion 710₁ and a second portion 710₂. The second traces 710₁-710₂ are identical or similar to the second traces 628 in FIG. 6, and thus the detail is not repeated herein. The microbumps 706 are formed on the second traces 710₁-710₂, and the joint parts 708 are disposed between the first portion 704₁ (of the first traces) and the microbumps 706, wherein the joint parts 708 comprise an intermetallic compound (IMC). In some embodiment, the intermetallic compound is a copper-rich compound such as Cu₆Sn₅ or Cu₃Sn for better electromigration resistance and reliability performance. In some embodiments, each of the joint parts 708 contains 50 vol. % or more of the intermetallic compound based on a total volume of each of the joint parts 708. In some embodiments, each of the joint parts 708 contains substantially 100 vol. % of the intermetallic compound based on a total volume of each of the joint parts 708.

In some embodiments, the microbumps 708 are also disposed between the UBM pads P1 and the second portion 710₂ (of the second traces), and the joint parts 708 are also disposed between the microbumps 706 and the UBM pads P1. In some embodiments, the microbumps 708 are in direct contact with the UBM pads P1 and the microbumps 706. In some embodiments, a thickness t5 of the microbumps 706 below the first portion 704₁ (of the first traces) is thicker than a thickness t6 of the microbumps 706 below the second portion 704₂ (of the first traces). In some embodiments, a ratio of the thickness t5 to the thickness t6, for instance, is 1.5 or more such as 2 or more. However, the present disclosure is not limited thereto. The microbumps 706 may be formed, for example, by two photomask processes in which the first photomask process is for forming thinner microbumps 706 and the second photomask process is for forming thicker microbumps 706. However, the present disclosure is not limited thereto. In some embodiments, the UBM pad P2 is electrically connected to the TIV 142.

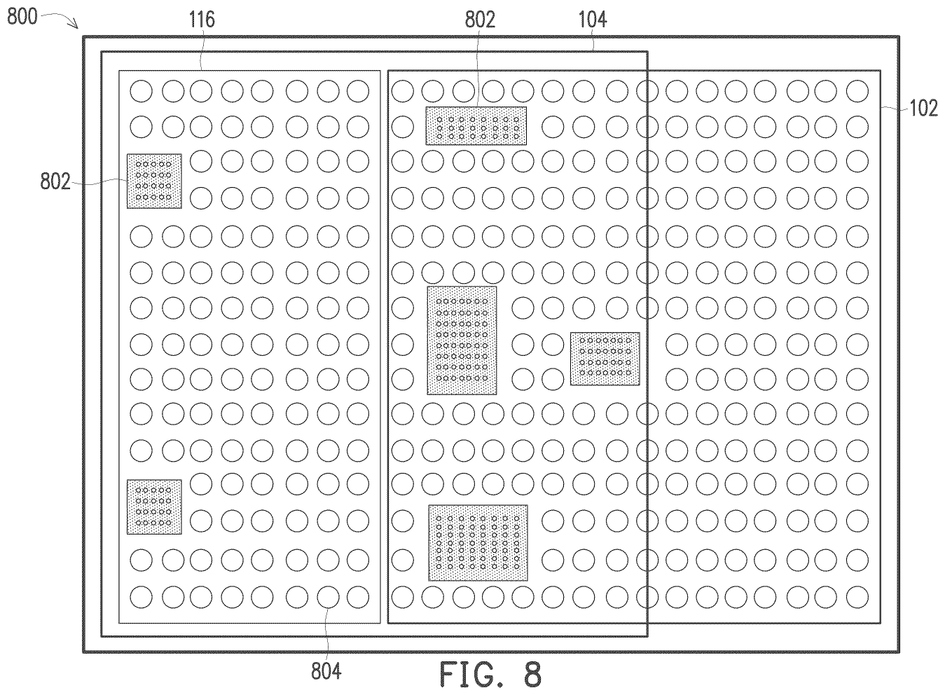

FIG. 8 illustrates a layout diagram in a plan view of a semiconductor device 800 in correspondence with the semiconductor package structure of FIG. 7. In FIG. 8, the locations of the first die 102, the second die 104, and the dummy die 116 are represented by three blocks. The blocks 802 with small circles represent the locations of the connections with fine pitch such as Core D2D talk fine pitch area and peripheral IO area. The larger circles 804 represent the locations of the connections with larger pitch such as Core power area with 80-250 μm pitch. In some embodiments, the region without the protective layer 702 and the UBM pads P1-P2 in FIG. 7 may be designed in the blocks 802, and the region with the protective layer 702 and the UBM pads P1-P2 in FIG. 7 may be designed in the circles 804.

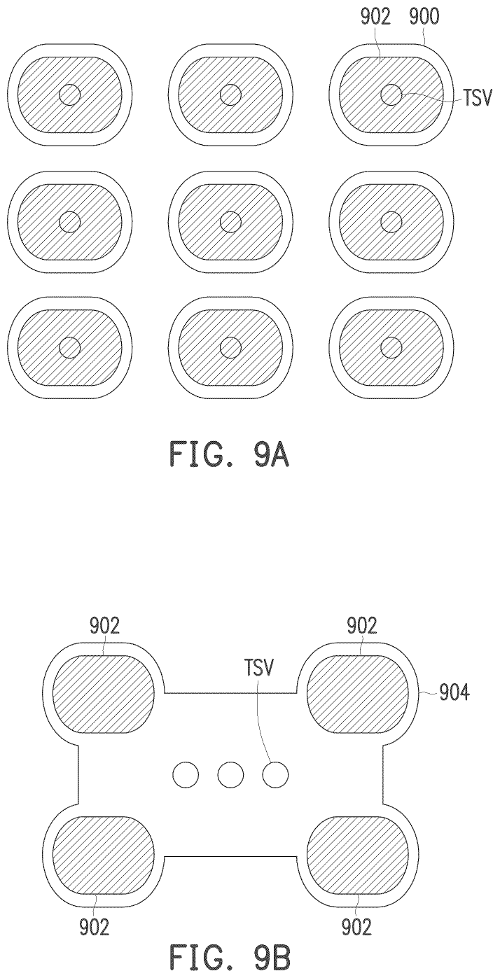

FIG. 9A shows a layout diagram in a plan view of the intermediate structure (i.e. the blocks 802) in correspondence with the semiconductor device of FIG. 8. In FIG. 9A, the number 900 represents the first portion 710₁ (of second traces) over the second bonding surface S2 of the second die 104 in FIG. 7, the number 902 represents the microbumps 706 over the first portion 710₁, and TSV represents through semiconductor vias in the second die 104.

FIG. 9B shows a layout diagram in a plan view of the intermediate structure (i.e. the circles 804) in correspondence with the semiconductor device of FIG. 8. In FIG. 9B, the number 904 represents the second portion 710₂ (of second traces) over the second bonding surface S2 of the second die 104 in FIG. 7, the number 902 represents the microbumps 706 over the second portion 710₂, and TSV represents through semiconductor vias in the second die 104. In some embodiments, the second portion 904 may has a butterfly shape, and the microbumps 902 are disposed over four wing ends of the butterfly shape. In some embodiments, the through semiconductor vias (TSV) are disposed at positions corresponding to the center of the butterfly shape.

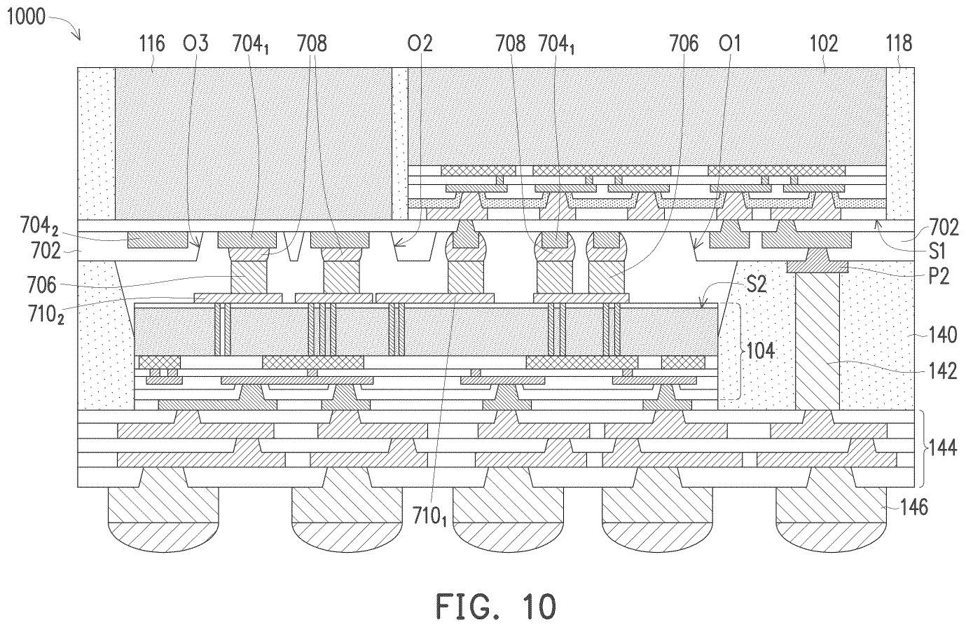

FIG. 10 illustrates a cross-sectional view of a semiconductor package structure 1000 in accordance with some embodiments of the present disclosure. In FIG. 10, a similar structure as that described above with respect to FIG. 7 is illustrated where like reference numerals indicate like elements. Thus, for convenience of description, differences with the semiconductor package structure 700 described above will be mainly described below.

Referring to FIG. 10, the semiconductor package structure 1000 has the UBM pad P2 and the protective layer 702, wherein the protective layer 702 has the opening O1 exposing a first portion 704₁ below the first die, an opening O2 below the dummy die 116, and an opening O3 exposing a first portion 704₁ below the dummy die 116. The second portion 704₂ is covered by the of the protective layer 702, and the UBM pad P2 is formed on the protective layer 702 and penetrates through the protective layer 702 to electrically connect the TIV 142 with the second portion 704₂.

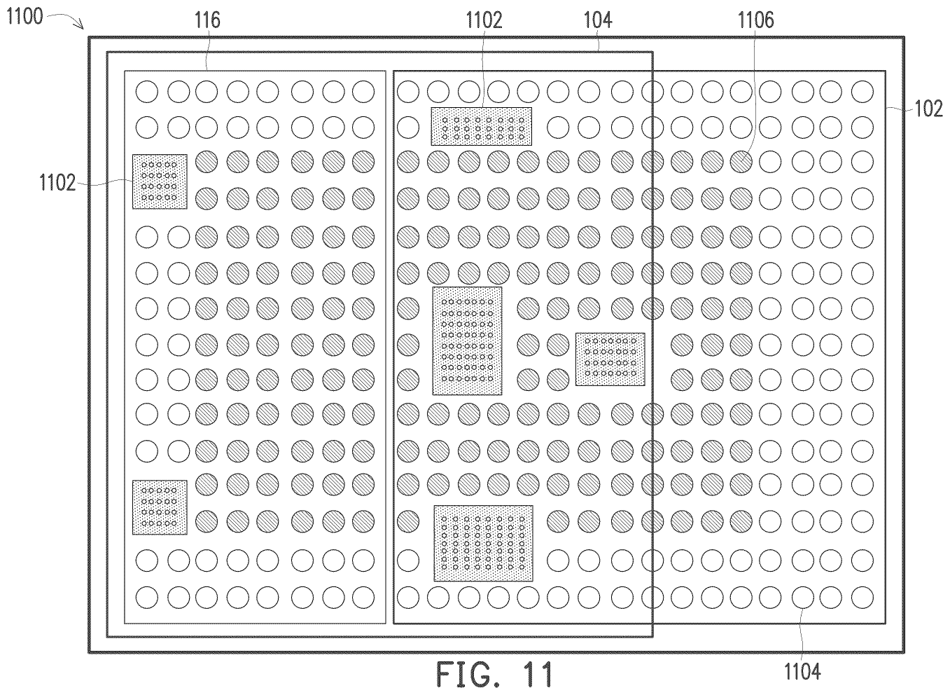

FIG. 11 illustrates a layout diagram in a plan view of a semiconductor device 1100 in correspondence with the semiconductor package structure of FIG. 10. In FIG. 11, the locations of the first die 102, the second die 104, and the dummy die 116 are represented by three blocks. The blocks 1102 with small circles represent the locations of the connections with fine pitch such as Core D2D talk fine pitch area. The circles 1104 represent the locations of the connections such as peripheral IO area with 25-80 μm pitch. The circles 1106 represent the locations of the connections with larger pitch such as Core power area with 80-250 μm pitch. In some embodiments, the region within the opening O1 in FIG. 10 may be designed in the blocks 1102 and the circles 1104, and the region within the openings O2 and O3 in FIG. 10 may be designed in the circles 1106. In some embodiments, each of the microbumps in the blocks 1102 and the circles 1104 may have an oblong shape, and each of the microbumps in the circles 1106 may have a round shape. However, the present disclosure is not limited thereto.

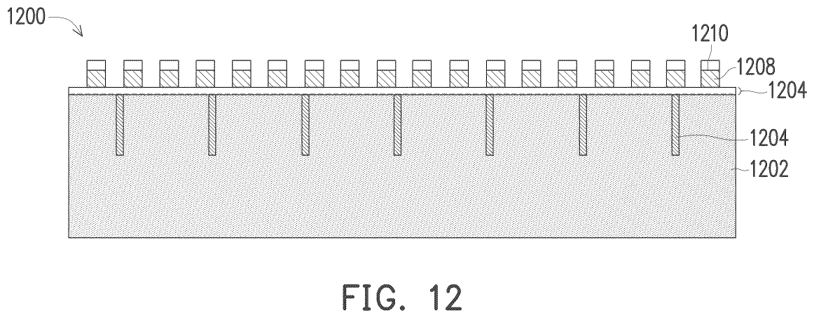

FIGS. 12 through 19 are cross-sectional views of a process for the formation of a semiconductor package structure in accordance with some embodiments of the present disclosure.

Referring to FIG. 12, a second die 1200 is provided. In some embodiments, the second die 1200 includes a semiconductor substrate 1202, a plurality of TSVs 1204, a region 1206 including a plurality of devices, and a plurality of connectors 1208. In some embodiments, the semiconductor substrate 1202 is made of a suitable elemental semiconductor, such as crystalline silicon, diamond, or germanium; a suitable compound semiconductor, such as gallium arsenide, silicon carbide, indium arsenide, or indium phosphide; or a suitable alloy semiconductor, such as silicon germanium carbide, gallium arsenic phosphide, or gallium indium phosphide. In some embodiments, a material of the TSVs 1204 includes aluminum, titanium, copper, nickel, tungsten, or alloys thereof. In some embodiments, active components (e.g., transistors or the like) and/or passive components (e.g., resistors, capacitors, inductors, or the like) are formed in the region 1206. The connectors 1208 are identical or similar to the connectors 126 in FIG. 1, and in some embodiments, there is an interconnect structure (not shown) between the connectors 1208 and the region 1206, and the interconnect structure is identical or similar to the interconnect structure 124 in FIG. 1. In some embodiments, a mask film 1210 is formed each of the connectors 1208, but it is not limited thereto; in other embodiments, the mask film 1210 can be omitted.

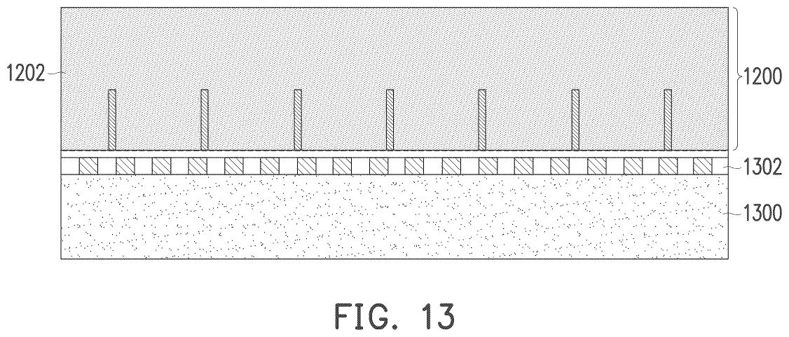

The structure, after the mask film 1210 is removed, is flipped over as shown in FIG. 13. Then, a carrier 1300 is provided to support the second die 1200. In some embodiments, a cap layer 1302 is formed before the carrier 1300 is applied. In some embodiments, a material of the cap layer 1302 include a polymer such as PBO, PI, a BCB based polymer, or the like. Other dielectric materials may also be used, including oxides, nitrides, carbides or combinations thereof.

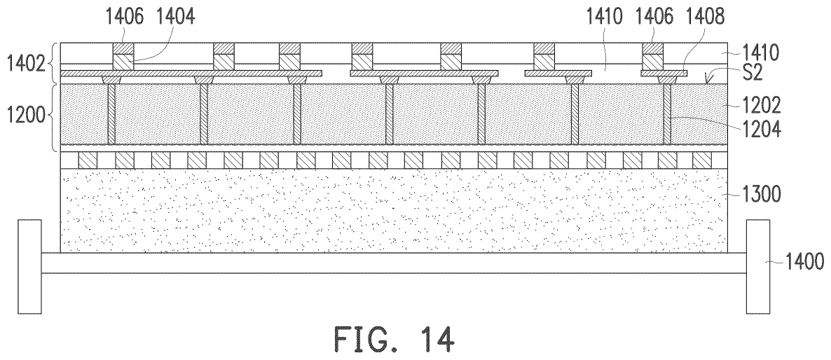

The structure is placed on a frame 1400 as shown in FIG. 14. Then, the semiconductor substrate 1202 is thinned to expose the TSVs 1204, and an intermediate structure 1402 is then formed over a second bonding surface S2 of the second die 1200 to connect with the TSVs 1204. In some embodiments, the semiconductor substrate 1202 may be thinned using a planarization process such as a CMP process, a grinding process, an etching process, the like, or a combination thereof. Other techniques are possible. The intermediate structure 1402 includes a plurality of conducive patterns 1408 and a plurality of dielectric layers 1410. The number of the dielectric layers 1410 or the conducive patterns 1408 is not limited by the disclosure. In some embodiments, dielectric materials for the dielectric layers 1410 include a polymer such as PBO, PI, a BCB based polymer; alternatively, oxides, nitrides, carbides or combinations thereof. In some embodiments, the conductive patterns 1408 are electrically connected to the TSVs 1204. In some embodiments, the dielectric layers 1410 include openings which are made by removing portions of the dielectric layers 1410 to expose at least a portion of the conducive patterns 1408. A plurality of microbumps 1404 are formed in those openings over the second bonding surface S2, and then a plurality of joint parts 1406 are formed on the plurality of microbumps 1404. In some embodiments, the plurality of joint parts 1406 are formed by initially forming a layer of solder, such as by evaporation, electroplating, printing, solder transfer, ball placement, or the like.

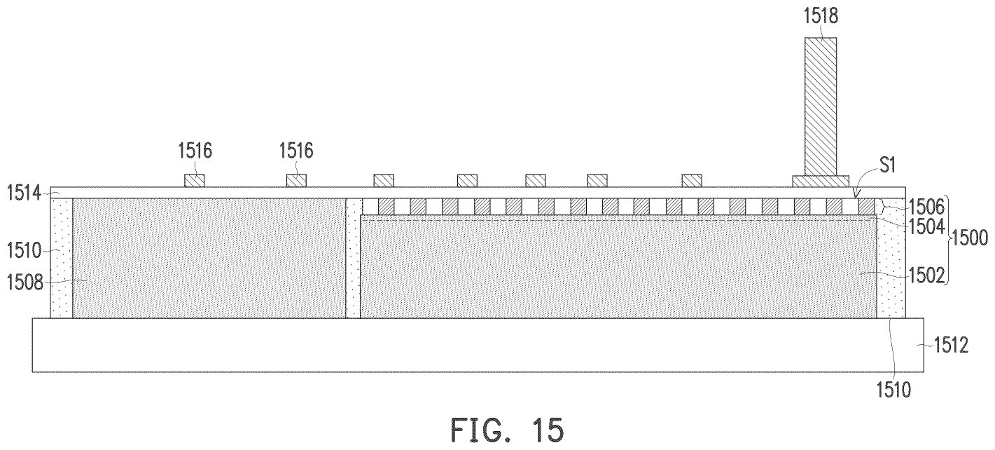

Referring to FIG. 15, a first die 1500 is provided over a carrier 1512. In some embodiments, the first die 1500 may include one or more logic dies (e.g., CPU die, GPU die, FPGA die, ASIC die, SoC die, SoIC die, microcontroller die, or the like), memory dies (e.g., DRAM die, SRAM die, HBM die, or the like), power management dies (e.g., PMIC die), RF dies, sensor dies, MEMS dies, signal processing dies (e.g., DSP die), front-end dies (e.g., AFE die), the like, or a combination thereof. In some embodiments, the carrier 1512 is a glass substrate, but it is not limited thereto. In some embodiments, the first die 1500 may includes a substrate 1502, a region 1504 including a plurality of devices and BEOL, and a connection structure 1506. In some embodiments, a dummy die 1508 may be disposed at one side of the substrate 1502. The dummy die 1508 is identical or similar to the dummy die 116 in FIG. 1, and thus the detail is not repeated herein. The first die 1500 and the dummy die 1508 may be encapsulated in an encapsulant 1510. In some embodiments, the encapsulant 1510 may comprise a molding compound, such as an epoxy, a resin, a moldable polymer, a combination thereof, or the like. In some embodiments, the first die 1500 has a first bonding surface S1, and then a dielectric cap layer 1514 is formed over the first bonding surface S1. In various embodiments, the dielectric cap layer 1514 is formed using, e.g., a spin-coating process, although any suitable method and thickness are also used. In some embodiments, a plurality of openings (not shown) may be formed in the dielectric cap layer 1514, wherein the openings are formed using photolithographic mask and etching processes, although other suitable processes are used in other embodiments. A plurality of traces 1516 are formed over the dielectric cap layer 1514, and in some embodiments, the traces 1516 may be formed of a conductive material, such as a metal (e.g. copper, or the like). A through integrated fan-out via (TIV) 1518 is optionally formed over the traces 1516. In some embodiments, the forming method of the TIV 1518 includes forming a photoresist layer such as a dry film resist on one of the traces 1516 and then forming an opening in the photoresist layer to expose a portion of the top surface of the one of the traces 1516, and forming a conductive layer on the one of the traces 1516 exposed by the opening by electroplating. Afterwards, the photoresist layer is stripped. However, other suitable processes are used in other embodiments.

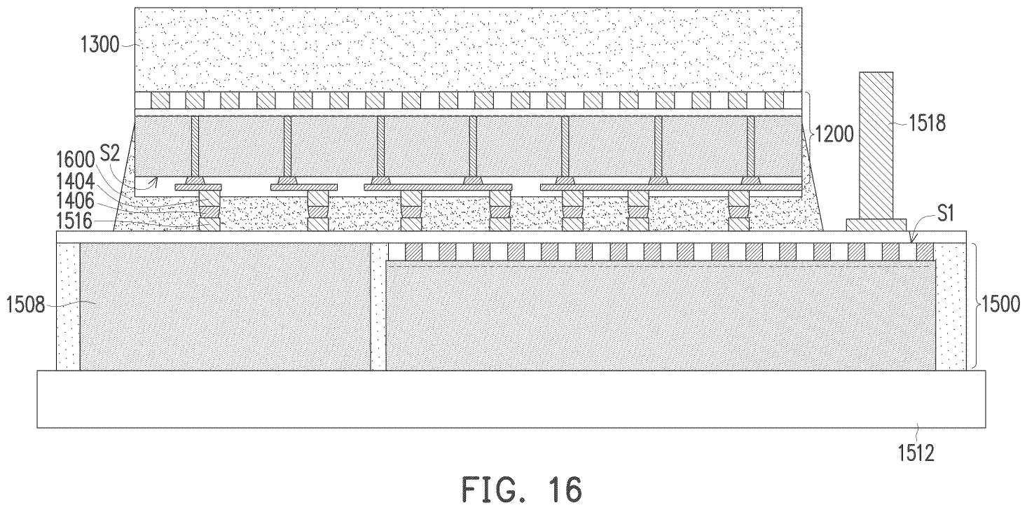

Referring to FIG. 16, the first die 1500 and the second die 1200 are joined by bonding the traces 1516 to the microbumps 1404 via the joint parts 1406. The joint parts 1406 comprises an intermetallic compound (IMC). In some embodiment, the intermetallic compound is a copper-rich compound such as Cu₆Sn₅ or Cu₃Sn for better electromigration resistance and reliability performance. In some embodiments, each of the joint parts 1406 contains 50 vol. % or more (e.g. 100 vol %) of the intermetallic compound based on a total volume of each of the joint parts 1406. In some embodiments, after jointing the first die 5100 and the second die 1200, a thermal treatment may be performed to increase a volumetric proportion of the intermetallic compound in the joint parts 1406. In some embodiments, after the thermal treatment, an underfill layer 1600 is formed to fill a space between the second die 1200 and the second die 1500. In some embodiments, the underfill layer 1600 may comprise a molding compound, such as an epoxy, a resin, a moldable polymer, a combination thereof, or the like. The molding compound may be applied while substantially liquid, and then may be cured through a chemical reaction, such as in an epoxy or resin. In other embodiments, the molding compound may be an UV or thermally cured polymer applied as a gel or malleable solid capable of being disposed around and between the second die 1200 and the second die 1500.

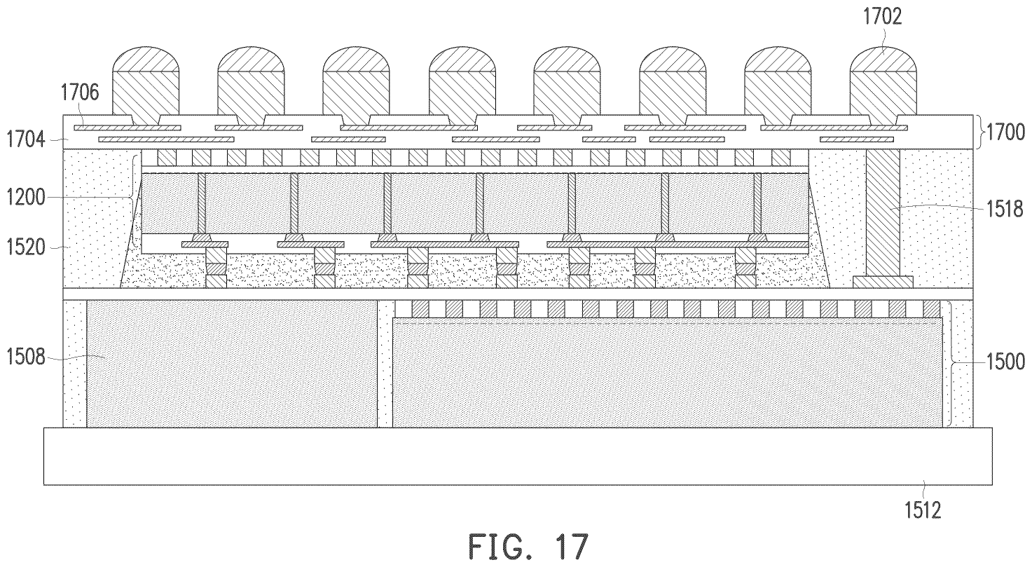

Referring to FIG. 17, after the carrier 1300 is removed, the second die 1200 and the TIV 1518 are encapsulated by an encapsulant 1520. The encapsulant 1520 is identical or similar to the encapsulant 1510 in FIG. 15, and thus the detail is not repeated herein. In some embodiments, the encapsulant 1520 is formed by forming an encapsulant material layer by a suitable fabrication technique such as spin-coating, lamination, deposition, or similar processes. The encapsulant material layer encapsulates the top surfaces and sidewalls of the second die 1200 and the TIV 1518. Thereafter, a planarization process such as a grinding or polishing process is performed to remove a portion of the encapsulant material layer, such that the top surfaces of the second die 1200 and the TIV 1518 are exposed. In some embodiments, the top surfaces of the second die 1200 and the TIV 1518 are substantially coplanar with each other. A redistribution layer (RDL) structure 1700 is then formed over the encapsulant 1520, wherein the RDL structure 1700 includes a plurality of polymer layers 1704 and a plurality of redistribution layers 1706. The number of the polymer layers 1704 or the redistribution layers 1706 is not limited by the disclosure. In some embodiments, the polymer layer 1704 includes a photo-sensitive material such as PBO, PI, a BCB based polymer, or the like. In some embodiments, the redistribution layers 1706 respectively include conductive materials. The conductive material includes metal such as copper, nickel, titanium, a combination thereof or the like. In some embodiments, a plurality of conductive connectors 1702 are formed on and electrically connected to the redistribution layers 1706 of the RDL structure 1700 to allow for the electrical coupling of the semiconductor package structure to external circuits or devices. The conductive connectors 1702 may be BGA connectors, C4 bumps, ENEPIG formed bumps, or the like.

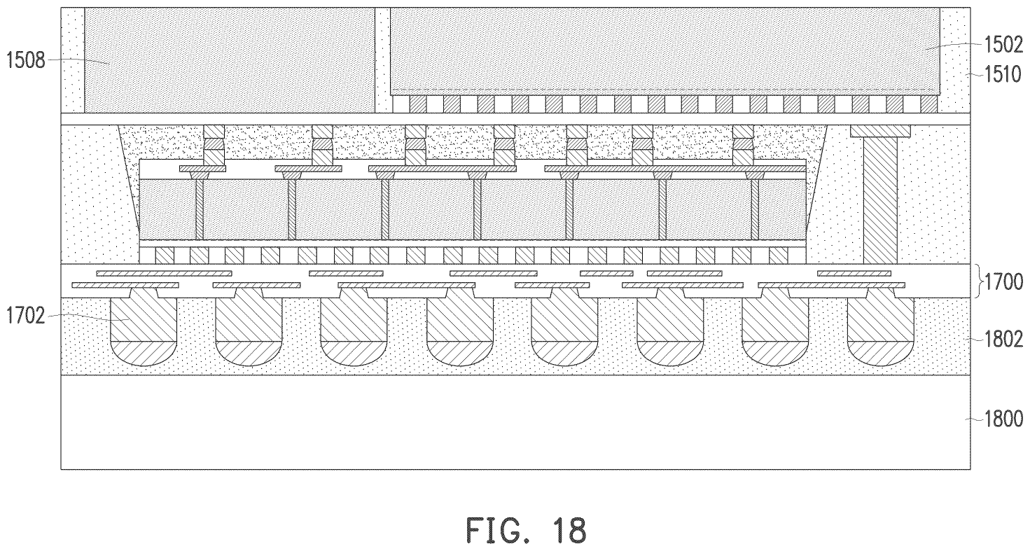

The structure, after the carrier 1512 is removed, is flipped over as shown in FIG. 18. An optional process may be performed to thin the substrate 1502 and the dummy die 1508. For example, the bottom of the structure (e.g. the conductive connectors 1702) are bonded to another carrier 1800 through the bonding material 1802, and then the substrate 1502 and the dummy die 1508 may be thinned using a planarization process such as a CMP process, a grinding process, an etching process, the like, or a combination thereof. Other techniques are possible.

Alternatively, the step of FIG. 18 may be omitted.

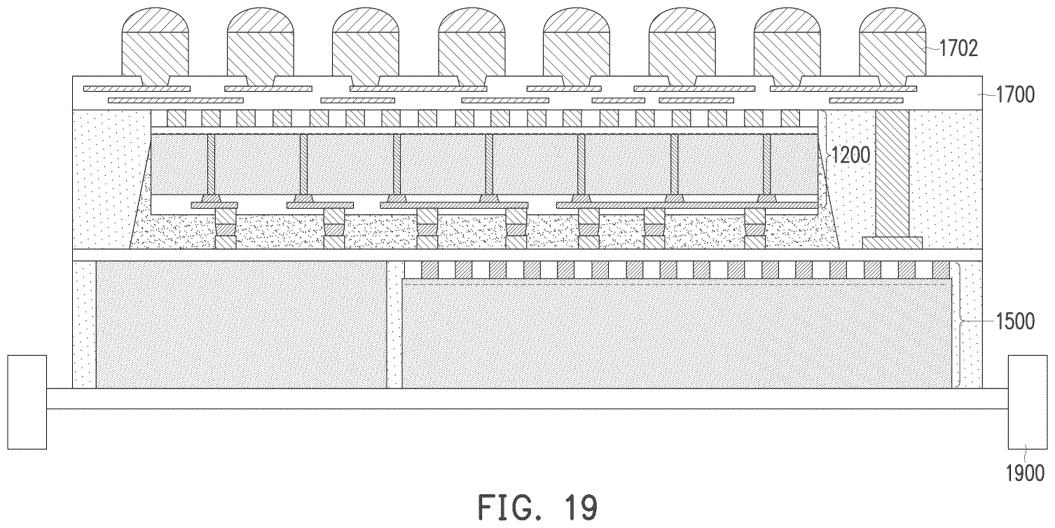

Referring to FIG. 19, after removing the bonding material 1802 and the carrier 1800, the resulting semiconductor package structure is placed on a frame 1900 and the conductive connectors 1702 are exposed to provide the electrical coupling to external circuits or device.

According to some embodiments, a semiconductor package structure includes a first die having a first bonding surface, a second die having a second bonding surface in which the second bonding surface faces the first bonding surface, and an intermediate structure between the first bonding surface and the second bonding surface. The intermediate structure includes a plurality of traces over the first bonding surface, a plurality of microbumps over the second bonding surface, and a plurality of joint parts between the traces and the microbumps, wherein the joint parts include an intermetallic compound.

According to some embodiments, a semiconductor package structure includes a first die, a protective layer, at least one under-ball metallurgy (UBM) pad, a second die, a plurality of microbumps, and a plurality of joint parts. The first die has a first bonding surface with a plurality of first traces, and the second die has a second bonding surface facing the first bonding surface, wherein the second bonding surface has a plurality of second traces. The protective layer is formed over the first traces, wherein the protective layer has at least one opening exposing a first portion of the first traces. The at least one UBM pad is formed on the protective layer and penetrates through the protective layer to electrically connect with a second portion of the first traces. The microbumps are formed on a first portion of the second traces. The joint parts are disposed between the first portion of the first traces and the microbumps, wherein the joint parts comprise an intermetallic compound.

According to some embodiments, a method for manufacturing a semiconductor package structure includes providing a first die having a first bonding surface; forming a plurality of traces over the first bonding surface; providing a second die having a second bonding surface; forming a plurality of microbumps over the second bonding surface; dispensing a plurality of joint parts on the plurality of microbumps; and jointing the first die and the second die by bonding the plurality of traces to the plurality of microbumps via the plurality of joint parts, wherein the plurality of joint parts comprises an intermetallic compound.

Other features and processes may also be included. For example, testing structures may be included to aid in the verification testing of the 3D packaging or 3DIC devices. The testing structures may include, for example, test pads formed in a redistribution layer or on a substrate that allows the testing of the 3D packaging or 3DIC, the use of probes and/or probe cards, and the like. The verification testing may be performed on intermediate structures as well as the final structure. Additionally, the structures and methods disclosed herein may be used in conjunction with testing methodologies that incorporate intermediate verification of known good dies to increase the yield and decrease costs.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor package structure, comprising:
a first die having a first bonding surface;
a second die having a second bonding surface, wherein the second bonding surface faces the first bonding surface; and
an intermediate structure between the first bonding surface and the second bonding surface, wherein the intermediate structure comprises a plurality of traces over the first bonding surface, a plurality of microbumps over the second bonding surface, and a plurality of joint parts between the traces and the microbumps, wherein the plurality of joint parts comprises an intermetallic compound.

2. The semiconductor package structure of claim 1, wherein the intermetallic compound in the plurality of joint parts is a copper-rich compound.

3. The semiconductor package structure of claim 1, wherein the intermetallic compound in the plurality of joint parts comprises Cu₆Sn₅ or Cu₃Sn.

4. The semiconductor package structure of claim 1, wherein each of the plurality of joint parts contains 50 vol. % or more of the intermetallic compound based on a total volume of each of the plurality of joint parts.

5. The semiconductor package structure of claim 1, wherein each of the plurality of joint parts contains substantially 100 vol. % of the intermetallic compound based on a total volume of each of the plurality of joint parts.

6. The semiconductor package structure of claim 1, wherein, in a plan view, each of the plurality of microbumps has an oblong shape, a rectangle shape, or a round shape.

7. The semiconductor package structure of claim 1, wherein one of the traces bonds to one of the microbumps via one of the joint parts.

8. The semiconductor package structure of claim 1, wherein a width of each of the plurality of microbumps is larger than a width of at least one of the traces.

9. The semiconductor package structure of claim 1, wherein a thickness of at least one of the joint parts is thicker than a thickness of each of the plurality of traces.

10. A semiconductor package structure, comprising:
a first die having a first bonding surface with a plurality of first traces;
a protective layer, formed over the first traces, wherein the protective layer has at least one opening exposing a first portion of the first traces;
at least one under-ball metallurgy (UBM) pad, formed on the protective layer and penetrating through the protective layer to electrically connect with a second portion of the first traces;
a second die having a second bonding surface facing the first bonding surface, wherein the second bonding surface has a plurality of second traces;
a plurality of microbumps, formed on a first portion of the second traces; and
a plurality of joint parts, disposed between the first portion of the first traces and the plurality of microbumps, wherein the plurality of joint parts comprises an intermetallic compound.

11. The semiconductor package structure of claim 10, wherein the microbumps are further disposed between the at least one UBM pad and a second portion of the second traces, and the joint parts are further disposed between the microbumps and the at least one UBM pad.

12. The semiconductor package structure of claim 11, wherein a thickness of the microbumps below the first portion of the first traces is thicker than a thickness of the microbumps below the second portion of the first traces.

13. The semiconductor package structure of claim 10, wherein the intermetallic compound in the plurality of joint parts comprises Cu₆Sn₅ or Cu₃Sn.

14. The semiconductor package structure of claim 10, wherein each of the plurality of joint parts contains 50 vol. % or more of the intermetallic compound based on a total volume of each of the plurality of joint parts.

15. The semiconductor package structure of claim 10, wherein each of the plurality of joint parts contains substantially 100 vol. % of the intermetallic compound based on a total volume of each of the plurality of joint parts.

16. The semiconductor package structure of claim 10, wherein, in a plan view, each of the plurality of microbumps has an oblong shape, a rectangle shape, or a round shape.

17. A method for manufacturing a semiconductor package structure, comprising:
providing a first die having a first bonding surface;
forming a plurality of traces over the first bonding surface;
providing a second die having a second bonding surface;
forming a plurality of microbumps over the second bonding surface;
dispensing a plurality of joint parts on the plurality of microbumps; and
jointing the first die and the second die by bonding the plurality of traces to the plurality of microbumps via the plurality of joint parts, wherein the plurality of joint parts comprises an intermetallic compound.

18. The method for manufacturing a semiconductor package structure of claim 17, wherein after jointing the first die and the second die, further comprises performing a thermal treatment to increase a volumetric proportion of the intermetallic compound in the plurality of joint parts.

19. The method for manufacturing a semiconductor package structure of claim 18, wherein after the thermal treatment, further comprises forming an underfill layer to fill a space between the first die and the second die.

20. The method for manufacturing a semiconductor package structure of claim 17, wherein the intermetallic compound in the plurality of joint parts comprises Cu₆Sn₅ or Cu₃Sn.
